(19) United States
(12) Patent Application Publication
(10) Pub. No.: US 2025/0296130 A1
(43) Pub. Date: Sep. 25, 2025

(54) DECENTRALISED, MODULAR SOLAR MODULE RECYCLING SOLUTION

(71) Applicant: ETAVOLT PTE LTD., Singapore (SG)

(72) Inventors: Qiu Xuan Cheryldine LIM, Singapore (SG); Zhi Peng LING, Singapore (SG); Chang-Kai Stanley WANG, Singapore (SG); Yong Heng SO, Singapore (SG)

(21) Appl. No.: 18/863,486

(22) PCT Filed: May 29, 2023
(86) PCT No.: PCT/SG2023/050379

§ 371 Date: Nov. 6, 2024

(30) Foreign Application Priority Data
Jun. 6, 2022 (SG) 10202250066F

(51) Int. Cl. B09B 3/35; B09B 101/15; B09B 101/50; H02S 50/10

(52) U.S. Cl. CPC B09B 3/35; H02S 50/10; B09B 2101/15; B09B 2101/50

(57) ABSTRACT

An assembly for recycling of PV waste within a container is disclosed. Within the container, there is provided the assembly for recycling solar panel, comprising (a) a deframer (20) for removing aluminium frames from each solar panel and junction boxes and copper wiring; (b) a portable I-V tester (30); (c) a shearing tool (41), air compressor and roller table (40) which is responsible for cutting up the deframed panels into smaller slices; (d) a first conveyor (50) and a second conveyor (70) used in transporting the sheared panel pieces from the shearing tool (41); (e) a crusher (60); (f) a sifter (80); and (g) a collection bag (90) to be used to collect recycled material from the sifter (80).

### CROSS-REFERENCE TO RELATED APPLICATION

This application claims the benefit of Singapore Provisional Application No. 10202250066F, filed 6 Jun. 2022, entitled “DECENTRALISED SOLAR MODULE RECYCLING SOLUTION”. The teachings of the foregoing application are hereby incorporated herein by reference.

### BACKGROUND OF THE INVENTION

### A. Field of the Invention

The present invention relates to recycling solution for modular solar module, and more particularly to a mobile, modular and decentralized system for solar module recycling.

### B. Background Art

In recent years, the rise in PV waste due to the increased capacity of silicon-based photovoltaic (PV) systems has led to a surge in recycling efforts. However, the traditional approach of large-scale central recycling facilities has several disadvantages. Firstly, since there is no constant supply of decommissioned panels from the local area, these facilities are only one-time use, making it difficult to justify the high capital investment. Secondly, transporting decommissioned solar panels from various locations to the central facility incurs significant transportation costs. Thirdly, shipping logistics may cause delays and impact the completion schedule of decommissioned panels. These factors create significant obstacles for PV recycling efforts and can lead to inertia in the community, potentially resulting in landfilling.

To have a better understanding of this market, it is relevant to refer to the regular reports by the International Renewable Energy Agency (IRENA). According to a recent solar photovoltaic (PV) report by IRENA (IRENA, Renewable Capacity Statistics, March 2021), the total energy produced from PV installations has reached >700 GW as of end 2020. This value is predicted to rise further to 1600 GW in 2030 and onwards to 4500 GW in 2050. This is a significant move towards reducing reliance on conventional energy sources which worsens the climate change issue. However, the amount of PV-related waste generated from these systems is expected to rise as well, where the current PV waste stands at 250k tonnes, and is predicted to increase to 8M tonnes by 2030 and 78M tonnes by 2050. If considering an average module power of 400 W, the total number of decommissioned solar panels amounts to 625k, 20M, and 195M pieces respectively. This is a massive quantity of decommission panels that needs to be handled in time to come.

At the moment, the conventional way of handling this PV waste is to turn to landfill dumping, which raises issues relating to the reduction in usable land space and increasing environmental pollution. It is also a huge waste of resources if these potentially reusable constituent materials within the solar panels end up disposed. Therefore, it is important to recycle these constituent materials as much as possible. In this regard, delivering a circular PV economy is necessary, which ensures the sustainability of the PV ecosystem both at the point of installation and at their end-of-life management. By breaking down the decommissioned solar panels into their respective components and repurposing these recovered materials back into new PV systems, millions of new panels can be reproduced, as shown in FIG. 8:

Referring FIG. 8, it can be seen that the cumulative PV capacity would reach 1600 GW by 2030 [1], while the cumulative PV panel waste would also reach to the scale of millions of tonnes as well. Therefore, it becomes necessary to recycle the components from these decommissioned panels, so that there would be enough raw material recovered to produce an equally enormous number of new panels-thus delivering a circular PV economy.

Currently, the development of solar module recycling plants is on the rise. The solar PV industry increasingly recognises for and agrees to the need to handle PV waste in a clean and green manner. However, it is often a huge investment, requiring large amounts of upfront capital and time to raise a capable facility from scratch. Large land spaces are also highly sought after for this purpose, which may not be accessible to all. Transportation efforts and costs must also be considered for PV owners who wish to decommission and recycle large quantities of solar modules at these recycling stations. As such, with the hassle of these consideration points above, an inertia might arise within the PV community towards solar panel recycling, which could ultimately lead back to landfilling.

In order to push for the encouragement of solar module recycling, this invention was created with the aim of recycling these solar panels on the go. A compact system is designed with the following solutions in mind—low upfront capital expenditure, portable and succinct recycling package, high transport mobility, and an excellent material recovery process on site. The key benefits of this tool and its various embodiments include: (i) compact, portable solar panel recycling solution, (ii) easy to transport with high mobility, (iii) solar panel recycling services available on-the-go, (iv) clean and green process with little environmental pollution, and (v) fast and efficient process with high throughput. By adopting the approach in this invention disclosure, solar modules can now be efficiently and effectively recycled in an environmentally friendly approach, anytime, anywhere.

At the end of this recycling process, the recovered materials will be: aluminium, glass, plastic, silicon, and copper.

A typical silicon-based solar panel contains the following components (FIG. 9): glass (74%), encapsulant (7%), silicon (3%), backsheet (4%), silver/Ag (0.05%), and other invaluable elements such as aluminium/Al, zinc, lead, copper and tin (11.95%). The values in brackets represent the weight percentages. Once extracted from the solar panels, these respective components can then be transferred into the next stage of recycling, where they will be passed on to both upstream and downstream partners. The upstream recyclers take in valuable metals such as Ag and Al, while the downstream recyclers take in the other components for proper disposal. Either way, a significant percentage (>90%) of these components can be reused and repurposed for a variety of applications such as newer solar panels, batteries for electric vehicles, and storage and transport materials for the hydrogen industry. This helps to establish a circular PV economy.

Currently, PV waste is handled either via landfilling or are recycled at e-waste facilities. Continuous landfilling contributes to the depletion of land space as well as chemical pollution from the breakdown of the solar panel constituents. On the other hand, the recycling of solar modules at e-waste facilities is often a better alternative but requires a higher upfront investment in terms of finances, land space, effort and time. Insofar, there has only been limited reports of a suitable improvement to this situation, and here is where this invention was created to address this problem.

### SUMMARY OF THE PRESENT INVENTION

It is an object of the present invention to provide decentralised, modular solar module recycling solution. The invention relates to a portable, compact solar module recycling system packaged within one 40-foot high cube containers. This container would house the main process line, which includes the following equipment: Roller table, shearing tool, crusher, sifter, and two conveyor belts. The supporting equipment includes the following equipment: Deframer, portable I-V tester, air compressor, diesel generator and collection bags.

The key benefits of this compact, mobile solution and its various embodiments include: (i) compact, portable solar panel recycling solution, (ii) easy to transport with high mobility, (iii) solar panel recycling services available on-the-go, (iv) clean and green process with little environmental pollution, (v) fast and efficient process with high throughput of up to 1 panel per minute, and (vi) customizable, modular design which can be integrated together to provide flexibility and throughput enhancement. By adopting the approach in this invention disclosure, solar modules can now be efficiently and effectively recycled in an environmentally friendly approach, anytime, anywhere. By adopting the approach described in this invention disclosure, solar panels can now be recycled efficiently and effectively on the go.

An object of the present invention is to provide a decentralised, modular solar module recycling solution, wherein the process flow for the recycling line is shown, and is described as follows:

Prior to recycling, the solar panels would be measured for their electrical properties using the portable I-V tester (current-voltage tester, in second container). This would identify panels which are still functional, or which could be reutilized elsewhere. These panels would not be highlighted for recycling, as they could be given a second life upon reutilization at another suitable site. Only the panels which are not functioning anymore would be proceeding on to the recycling process.

For the recycling process, firstly, the decommissioned waste panels would manually be loaded onto a mechanical deframer (second container). This machine would be capable of removing the junction boxes and copper wiring belonging to each solar module, after which, the aluminium frame encasing the solar module would then be dismantled. The recovered aluminium frames, junction boxes and copper wiring can then be shipped out from here to downstream services for further reusing or recycling. This deframer is an automated tool, but is not connected to the process line.

In the next step, the deframed solar panels would manually be loaded onto a roller table (first container). This roller table acts as an input feeder, and is connected to a shearing tool next on the process line. Both the roller table and the shearing tool are programmed and wired to each other. This allows the input feeding to be automated, from the roller table into the shearing tool. At this step, the deframed solar panels would be transferred into the shearing tool via the roller table, and the shearing tool would then shear the solar panels into smaller strips. Each sheared strip is roughly 12 cm×100 cm long, and this shearing process is automated. It is also the start of the main process line in the first container.

At the back of the shearing tool is an attached accessory labelled as the slider. This accessory is connected to a subsequent conveyor belt, and is required to rotate the orientation of the sheared piece by 90 degrees before it enters the belt. Once loaded onto this conveyor belt, the sheared piece would then be transported into the crusher.

The crushing stage is the next part of the process. At the crusher, the sheared piece would be milled into smaller pieces of the following sizes: 6 mm (collecting plastic; output 3), 2-6 mm (collecting glass; output 1), and less than 2 mm (silicon powder mixed with copper wiring; output 2). The 6 mm plastic output and 2-6 mm glass output would be collected and offloaded to down-takers. The remaining output which are less than 2 mm (the silicon powder mixed with copper wiring) would be sent into the next conveyor belt linking to the next stage, which is the sifting stage.

At this stage, the sifter would split the recovered output further into smaller size separations—larger than 2 mm (output 5), 0.5-2.0 mm (output 6), 0.315-0.5 mm (output 7), and less than 0.315 mm (output 8). This size distribution is described as follows: (1) The output larger than 2 mm would remove any particles that might have gotten into the initial mixture by accident (for example stray glass from the process line). This output would be manually inspected and would be combined into the correct collection bag before sending them out to down-takers. (2) The output which is within the 0.5-2.0 mm range would yield smaller glass particles and copper wiring. Similarly, this output would also undergo manual inspection before combining into the correct collection bag to send out to down-takers. (3) The output with particle size 0.315-0.5 mm and less than 0.315 mm would yield silicon powder. This silicon powder would be collated and be sent out to down-takers.

Yet another main object of the present invention is to provide a portable means to solar module recycling. The solution of this invention would transform the conventional centralized factory recycling process into a brand-new decentralized solution. At the end of the recycling process, a large bulk of the solar module would have been removed off and would be ready for downstream processing. This comprises the aluminium frame, the junction boxes, the copper wiring, and the glass pieces, which in total make up to ˜85% of solar module by weight. As covered above, the key novelty and benefits of this disclosed invention and its modified embodiments can be summarised as: (i) compact, portable solar panel recycling solution, (ii) easy to transport with high mobility, (iii) solar panel recycling services available on-the-go, (iv) clean and green process with little environmental pollution, and (v) fast and efficient process with high throughput of up to 1 panel per minute and (vi) customizable, modular design which can be integrated together to provide flexibility and throughput enhancement.

Using the approach in this invention disclosure, solar modules can be dismantled and recycled effectively and efficiently on the go. This provides PV owners a compact-sized, portable solar panel recycling solution at their doorstep with high mobility and easy transportation to their PV sites, a valuable option which cannot be offered by mainstream stationary e-waste recycling plants. Additionally, more than 85% of each solar module would be dismantled and be ready for further recycling and reusage at the end of this process, making this on par with the pre-treatment steps performed at the e-waste recycling plants. Each component of the solar modules would also be retrieved with high separation accuracy, which also brings their recovered purities on par with that obtained from the e-waste recycling plants.

Advantages and improvements over existing methods, devices or materials:

The key advantages for this invention over existing methods are summarised as follows:
1. Compact- and succinct-sized, takes up little landspace
2. Easy to transport, high mobility
3. Portable recycling service available on the go, anytime, anywhere
4. Clean and green process with little environmental pollution
5. Fast and efficient process with high throughput of up to 1 panel per minute that comes with automation
6. Recovered and dismantled materials have high purities (glass purity ˜96%, silicon purity ˜93%, aluminum purity ˜100%)
7. Excellent separation accuracy (recovery rate >90%)
8. Customizable, modular design which allows for integration to provide flexibility and boost throughput

The key industrial level/scale differentiators from this invention disclosure are:
1. The mobile solar module recycling process would be carried out inside a shipping container, which would be transported from site to site either via shipping and/or trailer transport.
2. Each individual station is designed to prepare the solar module for particle size separation at the end.
3. Process line is automated from the crusher onwards, requires minimal manual supervision. This allows for higher throughput for larger batches to be processed in each single run.
4. Process is largely clean, produces little waste by-products (<10%),
5. Stations are modular, and are easily modified to suit different needs. The entire integrated solution described in this invention disclosure is modular as well, offering customizability with respect to industrial needs,
6. Solution is highly scalable, and is easily transported to sites to cater for the different farm sizes or decommissioned panel quantities.

As proof of concept, several trial tests were performed on sample mini-modules. To begin with, a shearing test was performed with a shearing machine. The shearing results are as follows:

In FIG. 2, the mini-modules were seen to be sheared in a clean cut by the hydraulic shearing machine (left). The tempered glass on the mini-module had shattered upon impact, however, no flying shards were observed. Several cuts were attempted on this mini-module, and each cut could be reproduced cleanly. This shows that the shearing could be obtained well as long as the mini-module was aligned properly in line with the shearing machine.

Secondly, the sheared mini-modules were put through a shredding test via a shredder machine provided by another local collaborator. The results for this shredding test are shown below:

In FIG. 3, the particles collected from the shredding test were separated into two bags-one for a single shredding run (left), and one for a double shredding run (right). In the left image (single shredding), the mini-modules were shredded once, and the particles were collected immediately. The particle composition produced comprised glass shards (˜6 mm), mostly intact backsheet pieces in medium sizes and a fair bit of Si pieces. However, when the collected particles were sent for a second shredding round (right image), the larger pieces were size-reduced into smaller bits, and much more Si sand powder were observed to be produced. The particles obtained under this POC test could be selectively crushed with controllable particle sizes.

### BRIEF DESCRIPTION OF THE DRAWINGS

FIG. 1(a) schematically shows process flow for the recycling of solar modules within the portable recycling container in accordance with the present invention, wherein the process provides a high-level view of the recycling process;

FIG. 1(b) schematically shows process flow for the recycling of solar modules within the portable recycling container in accordance with the present invention, wherein the figure zooms in on the retrieved outputs for the crusher and the sifter;

FIG. 2 shows optical photos of the mini-modules, both sheared successfully (left) and pristine (right), wherein for the sheared mini-module, the cuts by the hydraulic shear machine were observed to be clean, and the tempered glass on the mini-module had shattered upon impact, but no flying shards were observed;

FIG. 3 shows collected particles for the shredded particles for one shred (left) and two shreds (right);

FIG. 4(a) is the top view of the preferred embodiment in accordance with the present invention;

FIG. 4(b) is the side view of the preferred embodiment in accordance with the present invention;

FIG. 5 schematically shows a dual container concept of another preferred embodiment in accordance with the present invention, wherein the first container houses the process line, while the second container houses the supporting equipment;

FIG. 6 shows schematically the thermic detachment process in accordance with the present invention, wherein the conveyor belt brings the deframed solar module from the deframer into the cordoned area, and the IR lamp and blade are pre-heated for at least 10 minutes prior to delamination;

FIG. 7 schematically shows process flow for the recycling of solar modules of another preferred embodiment in accordance with the present invention;

FIG. 8 shows exemplification of the circular PV economy by year 2030; and

FIG. 9 shows composition percentage of a typical solar panel.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

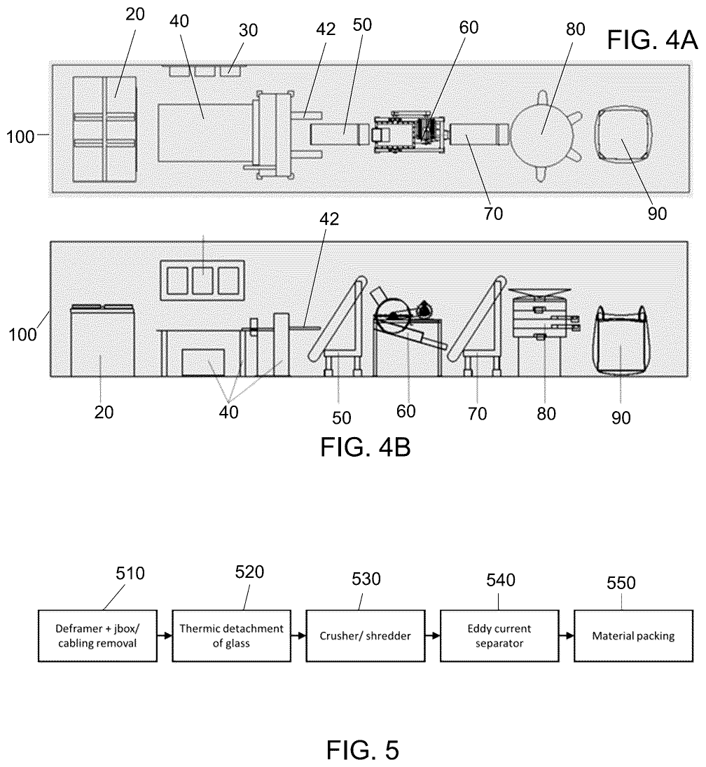

Referring to FIG. 4(a) and FIG. 4(b), there is shown process flow for the recycling of solar modules within a recycling container in accordance with the present invention.

### Preferred Embodiments

1. The design of the recycling container is described here (FIG. 4(a) and FIG. 4(b)). Container—the container (100) serves the main purpose of housing all the recycling components. The container (100) is to be of high cube model and 40 foot long with dimensions of 40′×8′×8′ 6″, equating to 12.2 m length×2.4 m width×2.6 m height. The long sides of this high cube container (100) are to be equipped with hydraulic doors capable of operating both manually and automatically. The roof is to be equipped with LED lightings of white, 2 stretches of 3 m each. A plurality of power sockets are to be installed inside this high cube container (100), comprising 3 three-phase sockets and 2 single-phase sockets. This high cube container (100) should be capable of holding at least 26.3 tonnes of weight, and is purchased commercially.

2. Portable I-V tester (30)—this portable IV tester (30) is required to identify the panels which are suitable for reutilization at another solar site. With portable IV tester (30), the IV characteristics (current-voltage) of each panel can be measured on site, which will give an indication of whether the panels are still functional. If they are, then these panels could be opted for reutilization instead of recycling. This IV tester (30) is 235 mm long, 165 mm wide, and 75 mm tall.

3. Deframer (20)—the first step of the recycling process starts with the deframer (20). It would be purchased commercially with equipment footprint of 1.7 m length×2.2 m width×2.6 m height. It has the sole purpose of removing the aluminium frames from each solar panel, as well as the respective junction boxes and copper wiring. It operates on a rated power of 2.2 KW, a rated voltage of 380 V, and a rated current of 8.2 A.

4. Shearing tool (41)—this tool (41) is responsible for cutting up the deframed panels into smaller slices. It is also purchased commercially with a footprint of 1.9 m length×1.3 m width×1.5 m height. It operates on rated specifications of 4 KW, 380 V and 16 A. There is a slider (42) attached at the back of the shearing tool (41) to slide the sheared slices by 90 degrees so that they would be in position for the conveyor belt (50) to transport into the crusher (60), and there would also be a roller table (40) installed in front of the shearing tool (41) so as to aid the shearing process. This roller table (40) is programmed with the shearing tool (41) such that the rolling process (into the shearing tool (41)) and the shearing process are synchronized with each other, and are automated.

5. Slider (42)—this slider (42) is responsible for rotating the sheared panel pieces into the correct orientation before entering the conveyor belt (first conveyor (50)) linking to a crusher (60). Any tool which utilizes this mechanism can be considered as part of the alternative embodiment.

6. The crusher (60)—there would be a conveyor belt connecting the shearing tool to the crusher (60). The sheared panel pieces would enter the crusher (60) via this conveyor belt connection. The crusher (60) named in this invention is obtained commercially with footprint of 1.7 m×0.6 m×1.4 m, and is powered by 4.5 KW, 380 V and 14 A. Beneath the crusher (60) are two separation meshes, 6.0 mm and 2.0 mm. This gives a size separation of more than 6.0 mm (output 3), between 2.0-6.0 mm (output 1), and less than 2.0 mm (output 2), collecting plastics, glasses, and silicon powder (mixed with copper wiring) respectively.

7. Sifter (80)—the main operation of the sifter (80) is to further separate the crushed particles into smaller sizes. There are three meshes installed inside the sifter (80)—2.0 mm mesh, 0.5 mm mesh, and 0.315 mm mesh. This gives a size separation of more than 2.0 mm (large glass which may have dropped into the initial output by accident; output 5), 0.5-2.0 mm particles (finer glass and copper wiring; output 6), 0.315-0.5 mm particles (silicon powder; output 7), and less than 0.315 mm particles (silicon powder; output 8). This sifter operates on 1.1 kW, 380 V, and 2.58 A. It is 1.3 m long, 1.1 m wide, and 1.2 m tall.

8. Conveyors (50, 70)—the conveyors (50, 70) used in this invention disclosure have a sole purpose of transporting the sheared panel pieces from the shearing tool (41) to the crusher (60), and the crushed pieces from the crusher (60 to the sifter (80). The conveyor belts (50, 70) are also angled at an incline to connect the lower heighted outputs of the mentioned equipment to the higher inlets of the next adjacent equipment.

9. Air compressor—this equipment is required for the operation of the roller table, as the rolling mechanism for this roller table functions via a pneumatic pressure system.

10. Collection bag (90)—the bags (90) to be used are made of woven polypropylene (PP) of cubic dimensions (1 m×1 m×1 m). They are to be capable of holding 1000 kg of materials per bag and should also be waterproof. A top covering or a seal should be positioned at the top of the bag (90), while the bottom remains flat. The bags (90) should also contain at least four corner loops or extra long loops for effective transportation.

Apart from the recycling container, a portable space-efficient set up could also be included. This is a necessary complementation to the recycling container, and must be present for the entirety of the recycling process involving the compact recycling unit:
1. It is a named and marked space with a range of flexible dimensions for the purpose of the setting up of, storing of, moving of, and packaging of the solar modules and its relevant constituents such as the removed aluminium frames, the removed junction boxes, the glass panes both crushed and uncrushed, the backsheet containing solar cells both crushed and uncrushed and any other components belong partially and/or fully to the solar module set up.
2. This workspace is to be of dimensions ranging from 5 m×5 m to 10 m×10 m, and may include the setting up of tentage or any other form of sheltering.
3. It is also to include leeway for the treatment of operator(s) in case of emergency, and should remain neat and clear of obstacles and obstruction.
4. An optional usage of this space is to include a rest section for the operator(s).

### Overview of the Mobile Recycling Unit

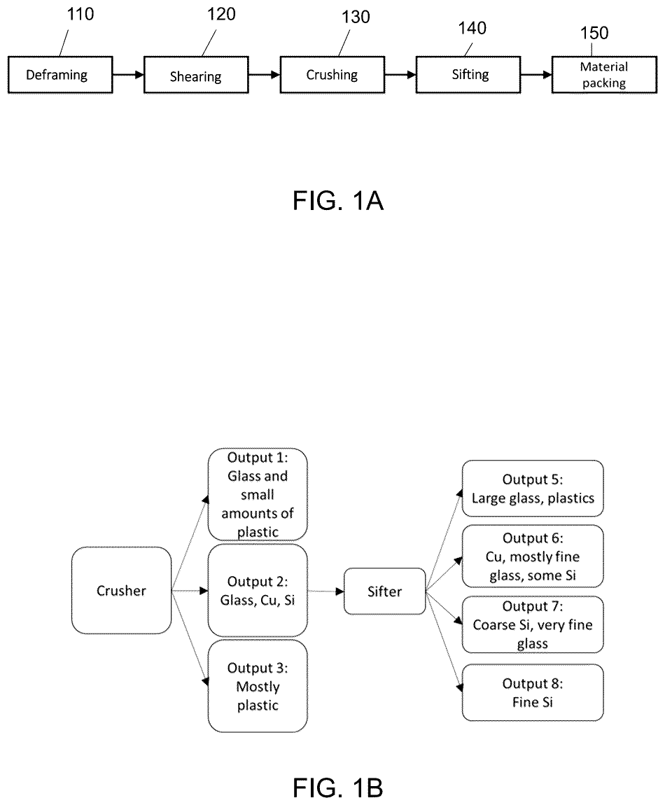

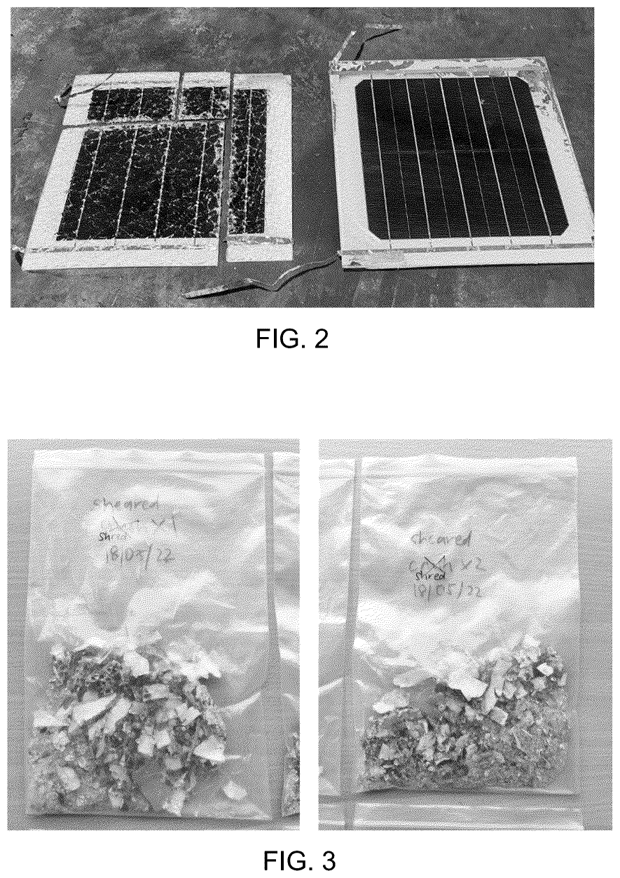

To explain briefly, the integrated recycling process starts from the deframer (left), and ends with the sifter (right), FIG. 4(a) and FIG. 4(b). The overview is shown in FIG. 1A. Solar modules are first sent to the deframer (110) to remove the aluminium frames, junction boxes and copper wiring. This covers the outer components of the solar modules.
1. After this step, the solar modules will then be sent to the shearing tool via manual unloading and loading onto the connected roller table, which would help to feed the deframed panel into the shearing tool. An automated, synchronized feed-shear cycle then begins to shear the deframed panel into thin slices. (120)
2. These thin slices would then slide down from the slider (attached to the back of the shearing tool) onto the first conveyor belt which would then transport the pieces into the crusher, where they would be crushed into smaller pieces which would exit the crusher via outputs 1, 2 or 3. (130)
3. Outputs 1 and 3 would be collected and sent off to down-takers at this stage.
4. Output 2 would continue to be transported to the sifter via the second conveyor belt. The sifter would then sort the particles out into outputs 5, 6, 7 or 8. (140)
5. Output 4 is denoted for another output from another process, and would not be discussed here in this current invention disclosure.
6. At the end of this separation, the recycling process is completed. (150)

The modifications of the preferred embodiments are described as follows:
1. Container—the preferred configuration of this container comprises fully automated doors on all sides powered by hydraulics. In the event that this cannot be automated, the doors should be able to function by manual labour. The doors should also be a single large component covering the entire length of container. However, smaller doors for compartmentalization purposes could be accepted as well.
   a. The ideal containment setup should include space/height considerations and therefore was presented as a high cube configuration. However, other arrangements such as the general purpose containers, double door containers, and open side containers which are suitable for this application could be considered as well.
   b. There should be sufficient lighting within this container, and this lighting should be manifested in the form of energy saving LEDs. Lighting on the exterior of the container could be considered for extra visibility. Torches/flashlights could be added for manual lighting.
   c. First aid kits should be available inside the container. Fire extinguishers could also be added.
   d. A separated compartment for emergency food supplies could installed.
   e. Emergency repair kits could be installed onboard in case of transport breakdown during travels.
2. Deframer (510)—the preferred deframing machine should ideally be capable of removing both the aluminium frames and junction boxes of the solar panels. It is to be purchased commercially. In the event that this is not possible and that the deframing machine has to be sourced from elsewhere, it should minimally have the capability of removing the aluminium frames from the solar modules. The removal of the junction boxes and the copper wirings could be performed with an additional embodiment. (510)
3. Shearing tool—any tool that could be used to cut the solar panel into smaller strips can be considered. So long as this tool is able to perform this function, it could be considered as a suitable variation to the tool described in this invention disclosure. Roller table—the main function of this table is to feed in deframed solar panels to the shearing tool. There is programming configured for this table and the shearing tool. As such, any other automation for this feeding process could be considered as a suitable variation to this contraption. The rolling mechanism functions via a pneumatic pressure system. Other alternative forms such as hydraulics could also be considered for this purpose.
4. Crusher—other suitable variations of crushers that could be accepted are the jaw crushers, the hammer crushers, the roll crushers, the impact crushers and the compound crushers. The ideal particle sizes that should be obtained with the crushing stage are 6 mm or lesser.
   a. Shielding is also required for the crusher. This is to protect the operators from potentially flying glass shards as the solar modules enter the crushing stage. The added shielding can be made out of any material, so long as it is able to handle the impact of flying glass shards without cracking or mechanically failing. It should also be transparent so that the viewing of the solar modules entering the crusher remains unobstructed.
5. Sifter—this tool operates on the base mechanism of a vibrating sift. When particles enter the sifter, it vibrates strongly and the particles would fall below and exit based on their mesh size. As such, it can be thought of as an automated separator. Any tool which fulfills this function could be considered as an alternative embodiment.
6. Diesel generator—the generator of choice in the above section is the diesel generator. However, other variants of generators would also be permissible given the right working conditions and circumstances. The other variants that could be considered are the portable generators, inverter generators, standby generators, gasoline generators, natural gas generators, solar generators and hydrogen generators. The diesel generator was chosen primarily due to the convenience of powering via diesel fuel. However, with other forms of energies that are accessible, the other variants of generators could be utilized.
   a. The diesel generator used in this recycling concept is preferred to have a 4-stroke engine. This is most efficient, because fuel is consumed once every 4 strokes. No pre-mixing of fuel is required, and the operation of this engine is considered to be environmentally friendly. However, this configuration contains more parts and is more costly to fix and maintain. As such, a more cost-effective alternative that could be considered would be the 2-stroke engine. Despite being the less fuel-efficient version, it has a much simpler design and is much easier to fix and maintain, hence making this a more viable fuss-free option.
   b. A generator canopy could also be considered to provide additional sound and vibration protection. Protection against weathering is also covered with the generator canopy. With this, it also protects the operators from several workplace hazards such as Hand-Arm Vibration, Whole-Body Vibration, and loss of hearing from prolonged noise pollution.
7. Collection bag—the bags to be used in the preferred embodiment are to be made of woven PP. However, another variant with added polyvinyl chloride (PVC) could also be considered. This form is imbued with extra durability and protection, amongst other advantages such as being lightweight, have dense, high strength, and are chemically resilient. These woven plastic bags are also watertight, which helps to ensure that the transport and storage of goods could be executed without the admission of water. Woven plastic is also soft and pliable, hence making them extremely flexible and space-adjusting for a plethora of applications. They are also highly recyclable and highly reusable, which fits remarkably into this concept of going green. The other requirement that must be met is the capability to hold ˜1 tonne of materials per bag, which would standardize a high loading for each transport.
8. Conveyor belt—there is a lot of flexibility to making adjustments to this embodiment. Other viable types of conveyor belts that could be considered are the roller bed conveyors, the flat belt conveyors, the modular belt conveyors, the cleated belt conveyors (inverted Ts, forward-learning Ls, inverted Vs, and lugs and pegs), the curved belt conveyors, the incline/decline belt conveyors, the washdown conveyors and several specialty conveyors such as fiberglass, metal nub, narrow-width, back-lit, vacuum, magnetic, and sandwich belt conveyors.

In a second alternative embodiment of the present invention, two containers are considered:
1. In the first container, the main processes are housed inside, which has been described in the earlier section on preferred embodiment. This encompasses the following tools such as: deframer, roller table, shearing tool, crusher, sifter, the respective two conveyors and the IV tester.
2. In the second container, the following supporting tools can be added:
   a. Diesel generator—in view that this recycling process would be executed often without access to an electrical point, a diesel generator is required to power the entire set up. This equipment could be put inside the supporting container. The diesel generator is to be of a standby model with a 4-stroke engine. In a 4-stroke diesel engine, the 4 stages of the engine's operations (intake, compression, ignition and exhaust) will take 2 complete revolutions. This enables the 4-stroke engine to be more fuel- and cost-efficient, because fuel is consumed every 4 strokes. As a result, scavenging does not occur with the 4-stroke diesel engine. Additionally, there should also be 3-4 three-phase outlets installed on this diesel generator. This equipment is to be purchased commercially.
   b. Large battery pack—this can also help to provide the power supply for the main container to function, and can also act as a standby power source. Both this battery pack and the diesel generator are complementary to each other
   c. Additional characterization tools—photoluminescent measurement tools (PL), solar panel inspection drones, and thermal imaging tools which aid in the assessment of the solar panels prior to recycling can be added to this container
   d. Peripheral supporting equipment—tools such as safety/first aid boxes, vacuum cleaners, and other miscellaneous items can be placed within this container

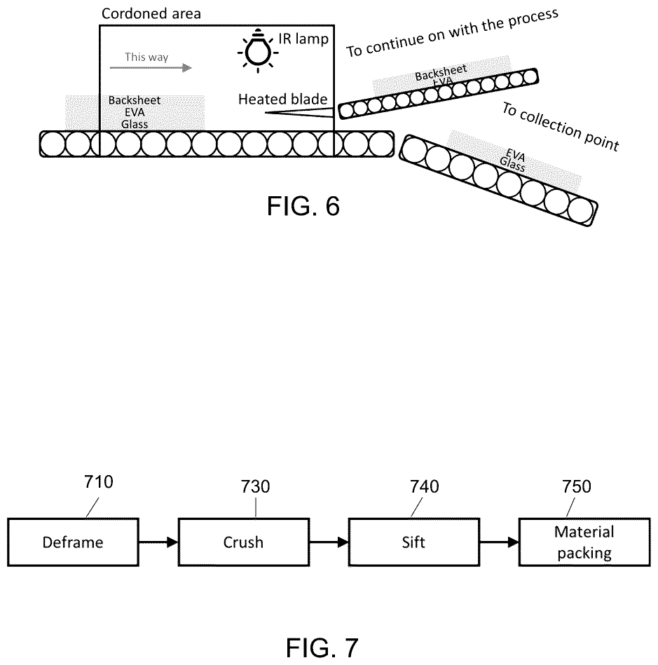

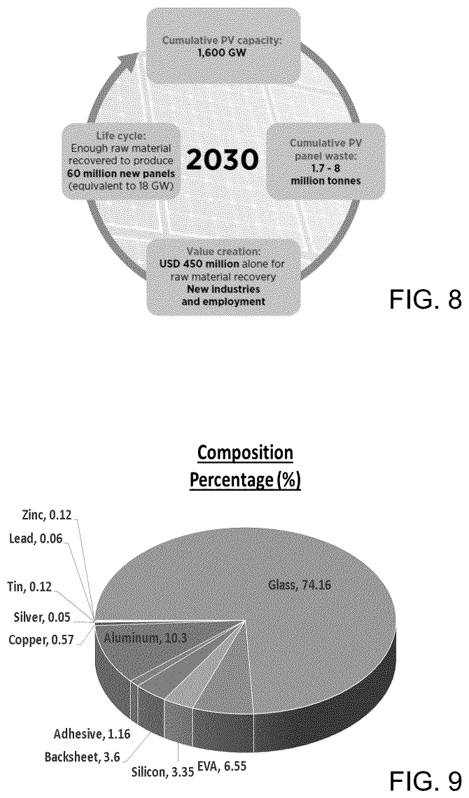

In the third alternative embodiment, the above considerations are added with the inclusion of two additional stage (FIG. 5 and FIG. 6):
1. Thermic detachment stage (520)—this is where the delamination of the glass pieces would take place. A sample schematic is provided in FIG. 6. A conveyor belt leading into a cordoned area (610) runs by automation. This cordoned area (610) comprises a heater, an attached, immobile blade (620) of 0.5 mm thickness, and an infrared (IR) lamp (630). The heater is affixed to the attached blade (620), and is responsible for heating the attached blade (620), while the IR lamp (630) is affixed to the top of the cordoned area (610) and is positionally adjacent to the blade. This IR lamp (630) is responsible for heating the front side of the solar module to aid with the delamination of the glass pieces off the backsheet containing the solar cells. The operation of this stage is described as follows:
   a. The attached blade (620) would be pre-heated to 300° C. (working range 200° C. to 320° C.). A continuous heating of this blade (620) is required for the entirety of this process.
   b. The IR lamp (630) would be turned on for at least 5 to 10 minutes. It should be capable of heating the front end of the solar module to at least 100° C. to 250° C. while the delamination of the glass piece is ongoing.
   c. The conveyor belt receives the deframed solar module free of its aluminium frame as well as its junction box. The belt pushes the solar module into the cordoned area at a slow rate of 0.5 to 1 cm/s. Accordingly, a solar module of 1.5 m length would require ˜75 to 150 seconds to be delaminated.
   d. As the solar module enters the cordoned area, the IR lamp (630) would heat up the front side of the solar module, while the heated blade (620) would start to pierce into the encapsulant layer (ethylene vinyl acetate; EVA).
   e. As the belt continues to push the solar module in further, the blade continues to penetrate the EVA layer (650). This proceeds until the entire module traverses across the cordoned area (610) and the entire EVA layer (650) has been sliced through. The glass piece would then be removed completely from the backsheet layer (640) containing the solar cells. The glass piece would be removed from the line, and the backsheet (640) with the solar cells would continue on the recycling process.
   f. At the exit of the cordoned area (610), there would be a collection point for the glass piece and a continuation pathway for the backsheet with the solar cells. Depending on how the solar module was positioned at the deframing stage, it would enter this delamination stage with the same configuration (either glass top+backsheet bottom, or glass bottom+backsheet top). Accordingly, the collection point and the continuation pathway could be adjusted.
   g. The delaminated glass panel could also be sent to the crushing/crushing stage (530) to be broken down into smaller pieces so that its packing (550) would become more space-saving and its transportation to downstream receivers could be better managed.
2. Eddy current separator (540)—the main function of this tool is to separate out the metals from the non-metals. This step aids in retrieving the copper strips and ribbons from the interconnects within the solar panels. Any tool which fulfills this function could be considered for this alternative embodiment.

In the fourth alternative embodiment, the setup is much simpler with the equipment (FIG. 7). In this alternative, only a deframer for deframing (710), a full-sized crusher for crushing (730) of the sheared solar module, a sifter used in sifting of crushed materials into different sizes (740) and storage bags for material packing (750) are present:
1. Once the aluminium frames and junction boxes are removed off the solar modules, they would be sent to the crusher for size reduction.
2. The stripped solar module would then be transported back to the central facility for additional processing in its entirety i.e. no crushing/crushing.

This invention can be applied to the recycling of the following types of solar modules: both p- and n-type silicon monofacial solar modules, both p- and n-type silicon bifacial solar modules, straight/regular solar modules, bent/odd-shaped solar modules, frameless solar panels, as well as monocrystalline, polycrystalline and amorphous silicon solar modules. Single, standalone solar cells and wafers could also be recycled with this technology, which includes solar cells and wafers that were partially processed, and low grade/scrapped cells which were rejected from manufacturing plants, EPC and O&M companies. Thin film solar modules can also be deframed with this invention, which also helps to save logistic costs in the long run. Overall, this allows us to extend our recycling outreach to more areas within the PV industry.

The embodiments described in this invention disclosure are highly adjustable as well. This enables the recycling of solar cells and modules of varying dimensions. By extension, it also allows for this invention to cater to past, present and future types of solar modules, with the past modules manufactured with smaller dimensions, and future modules inclusive of a greater solar cell count per module. This is important for the long-term sustainability of this invention and its recycling initiative.

The recovery of the respective components of each solar module is also distinctively segregated at each stage. Potentially, these materials could be retrieved on the spot and be packed for shipment to downstream handlers. The value/costs of these extracted materials would go through a purity grading system by the downstream takers; however, all materials can be accepted.

Overall, such decentralized, modular, easily deployed and highly scalable container solution would be able to accelerate the market opening for solar recycling and would also be able to contribute to the growing global solar e-waste problem solving.

The limitations are stated as follows:
1. Automation is required for each equipment to be used on board, which when operational for many hours in a day, would be demanding for energy consumption. This in turn translates to a large intake of diesel fuel, which contradicts against the going green initiatives. Although the diesel generator is recommended to have a 4-stroke engine which conceptually is environmentally friendlier, the need for diesel consumption is still inevitable. Solar-based generators could be considered alternatively, but as of current technology, the power output produced by solar PV technologies of this scale would be insufficient to power this heavy-duty recycling invention. The same applies to rechargeable batteries-too large a large quantity of those would be needed.
2. This invention does not contain any methods of purification. All recovered materials are to be taken as they are without further processing. As such, this invention cannot serve as a total turnkey solution, but instead, is only an intermediary step to complete module recycling.

There are several challenges associated with the integration of this invention disclosure:
1. The heights of the inlets and outlets of each equipment must be taken into account when designing the specifications of the conveyor belts. This is important to ensure that the connection between each tool via the conveyor belts is tight, which will prevent leakage of materials as they traverse through the different processing stages.
2. The throughput of the overall line is gated by the equipment with the lowest throughput i.e. this tool would be the bottleneck for the entire process line. As such, the relative speeds of the other components of the line (moving speed for conveyor belts and processing speed for each equipment) needs to be calibrated with respect to the tool that is the bottleneck. This is important to ensure that the process line has a smooth flow, and also to prevent clogging up of the line in the case that either tool/stage is proceeding at a much faster rate.
3. The dimensions of the process line need to be taken into consideration with respect to the dimensions of the housing container. As described earlier, the process line begins with the shearing tool (+ roller table), and ends with the sifter. Inbetween, there is the crusher and the conveyor belts. In total, there are 3 process tools and 2 conveyor belts that make up the process line. This is a sizable line, considering that these equipment are industrial-level tools (large equipment footprint).
   a. In parallel, this invention disclosure aims to provide a portable, compact, mobile solution for solar panel recycling. Hence, the housing for such a solution needs to be constricted in footprint.
   b. This creates a contradiction, where the challenge is to constrain the entire turnkey solution into this small, restricted space. This is where the integration of the process line into its housing becomes important, where the connections between each tool and each portion need to be tight and space-saving.

Since certain changes may be made in the foregoing disclosure without departing from the scope of the invention herein involved, it is intended that all matter contained in the above description and depicted in the accompanying drawings be construed in an illustrative and not limiting sense.

The foregoing is illustrative of the present invention and is not to be construed as limiting thereof. Although exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. This invention is defined by the following claims, with equivalents of the claims to be included therein.

1. An assembly for recycling of PV waste within a container comprising
(a) a deframer (20) for removing aluminium frames from each solar panel and junction boxes and copper wiring;
(b) a portable I-V tester (30) which is used to identify the panels which are suitable for reutilization at another solar site;
(c) a shearing tool (41), air compressor and roller table (40) which is responsible for cutting up the deframed panels into smaller slices;
(d) a first conveyor (50) and a second conveyor (70) used for transporting the sheared panel pieces from the shearing tool;
(e) a crusher (60) linked to the first conveyor (50) to crush the sheared panel pieces into smaller pieces, said sheared panel pieces entering the crusher (60) via the first conveyor (50); wherein the
(f) a sifter (80) linked to the second conveyor (70) and being used to further separate the crushed particles into smaller sizes, wherein there are three meshes installed inside the sifter, wherein the second conveyor (70) is linked to the sifter (80); and
(g) a collection bag (90) to be used to collect recycled material from the sifter (80).

2. The assembly for recycling of PV waste within a container as set forth in claim 1, wherein the first conveyor (50) is angled at an incline to connect a lower heighted output of the shearing tool (41), air compressor & roller table (40) to a higher inlet of the crusher (60).

3. The assembly for recycling of PV waste within a container as set forth in claim 1, wherein the second conveyor (70) is angled at an incline to connect a lower heighted output of the crusher (60) to a higher inlet of the sifter (80).

4. The assembly for recycling of PV waste within a container as set forth in claim 1, wherein the portable IV tester provides the IV characteristics (current-voltage) of each panel which will give an indication of whether the panels are still functional and opted for reutilization instead of recycling.

5. The assembly for recycling of PV waste within a container as set forth in claim 1, wherein the roller table (42) is programmed with the shearing tool (41) such that the rolling process of the roller table (40) and the shearing process of the shearing tool (41) are synchronized with each other and are automated.

6. The assembly for recycling of PV waste within a container as set forth in claim 1, further comprising a slider (42) which is used for rotating the sheared panel pieces into correct orientation before the sheared panel pieces enter the first conveyor (50) linking to the crusher (60).

7. The assembly for recycling of PV waste within a container as set forth in claim 1, wherein the air compressor is used for the operation of the roller table and the rolling process of the roller table (40) is operated via a pneumatic pressure system.

8. The assembly for recycling of PV waste within a container as set forth in claim 1, wherein the assembly is highly mobility and the recycling process is environment friendly.

9. The assembly for recycling of PV waste within a container as set forth in claim 1, wherein each of components of the solar modules is retrieved with high separation accuracy.

10. The assembly for recycling of PV waste within a container as set forth in claim 1, wherein the container (100) is a high cube model and 40 foot long with dimensions of 40′×8′×8′ 6″, equating to 12.2 m length×2.4 m width×2.6 m height.

11. The assembly for recycling of PV waste within a waste as set forth in claim 10, wherein a plurality of long sides of the container are equipped with hydraulic doors capable of operating both manually and automatically.

12. A method of recycling of PV waste within a container comprising the steps of
(i) deframing of aluminium frames and junction boxes of solar panels;
(ii) shearing of the solar panels into long strips using a shearing tool;
(iii) crushing the sheared long strips of solar panels by a crusher in step (ii);
(iv) sifting of the crushed materials by a sifter into different sizes; and
(v) collecting and packing of the sifted materials to be sent to a central facility for advanced recycling or be sent to down-takers for other application.

13. The method of recycling as set forth in claim 12, wherein in step (iii), 3 outputs respectively provide glass and small amounts of plastic, glass, copper and silicon, and mostly plastic.

14. The method of recycling as set forth in claim 12, wherein in step (iv) 4 outputs respectively provide large glass & plastics, copper, fine glass and some silicone, coarse silicon & very fine glass, and fine silicon.

15. The method of recycling of PV waste within a container as set forth in claim 12, further comprising the step of (ia) thermic detaching where delamination of glass pieces of a solar panel is taken place, wherein an attached blade is pre-heated to 300° C. to delaminate the glass pieces.

16. The method of recycling of PV waste within a container as set forth in claim 15, wherein an IR lamp is provided to a condoned area of the container for the heating of the front end of the solar panel to a temperature of at least 100 to 250° C.

17. The method of recycling of PV waste within a container as set forth in claim 16, wherein a heated blade is provided at the condoned area of the container to pierce into the solar panel via encapsulant layer thereof.

18. The method of recycling of PV waste within a container as set forth in claim 12, wherein the crusher is provided with two separation meshes, 6.0 mm and 2.0 mm, locate beneath the crusher, and wherein a size separation of more than 6.0 mm, and between 2.0-6.0 mm, and less than 2.0 mm, collecting plastics, glasses, and silicon powder (mixed with copper wiring) respectively.

19. The method of recycling of PV waste within a container as set forth in claim 12, wherein the sifter is provided with three meshes installed inside the sifter—2.0 mm mesh, 0.5 mm mesh, and 0.315 mm mesh, which gives a size separation of more than 2.0 mm, 0.5-2.0 mm particles, 0.315-0.5 mm particles, and less than 0.315 mm particles.

20. The method of recycling of PV waste within a container as set forth in claim 12, wherein conveyors used in transporting sheared panel pieces from the shearing tool to the crusher, and the crushed pieces from the crusher to the sifter.
